(19) United States
(12) Patent Application Publication
(10) Pub. No.: US 2023/0033058 A1
(43) Pub. Date: Feb. 2, 2023

(54) REACTOR WITH INDUCTIVELY COUPLED PLASMA SOURCE

(71) Applicant: Applied Materials, Inc., Santa Clara, CA (US)

(72) Inventors: Khokan Chandra Paul, Cupertino, CA (US); Truong Van Nguyen, Milpitas, CA (US); Diwakar Kedlaya, San Jose, CA (US); Maziar Aghvami, San Francisco, CA (US); Vijet Patil, Bangalore (IN); Shashank Sharma, Raipur (IN)

(73) Assignee: Applied Materials, Inc., Santa Clara, CA (US)

(21) Appl. No.: 17/389,103

(22) Filed: Jul. 29, 2021

(51) Int. Cl. H01J 37/32

(52) U.S. Cl. CPC H01J 37/321; H01J 37/32651; H01J 37/32724; H01J 37/3244; H01J 2237/332; H01J 2237/334

(57) ABSTRACT

Exemplary semiconductor processing systems may include an inductively coupled plasma source. The systems may include an RF power source that is electrically coupled with the inductively coupled plasma source. The systems may include a first gas source fluidly coupled with the inductively coupled plasma source. The systems may include a second gas source. The systems may include a dual-channel showerhead assembly defining a first plurality of apertures and a second plurality of apertures. The first plurality of apertures may be fluidly coupled with the inductively coupled plasma source. The second plurality of apertures are fluidly coupled with the second gas source.

### TECHNICAL FIELD

The present technology relates to components and apparatuses for semiconductor manufacturing. More specifically, the present technology relates to plasma generation devices and other semiconductor processing equipment.

### BACKGROUND

Integrated circuits are made possible by processes which produce intricately patterned material layers on substrate surfaces. Producing patterned material on a substrate requires controlled methods for forming and removing material. Chamber components often deliver processing gases to a substrate for depositing films or removing materials. Oftentimes, to produce high density films, higher processing temperatures and/or RF powers must be maintained, which may cause damage to the processing equipment and/or on wafer defects.

Thus, there is a need for improved systems and methods that can be used to produce high density films. These and other needs are addressed by the present technology.

### SUMMARY

Exemplary semiconductor processing systems may include an inductively coupled plasma source. The systems may include an RF power source that is electrically coupled with the inductively coupled plasma source. The systems may include a first gas source fluidly coupled with the inductively coupled plasma source. The systems may include a second gas source. The systems may include a dual-channel showerhead assembly defining a first plurality of apertures and a second plurality of apertures. The first plurality of apertures may be fluidly coupled with the inductively coupled plasma source. The second plurality of apertures may be fluidly coupled with the second gas source.

In some embodiments, the inductively coupled plasma source may include a dielectric tube defining an open interior. The inductively coupled plasma source may include a Faraday cage disposed about an exterior surface of the dielectric tube. The inductively coupled plasma source may include one or more RF coils disposed about an exterior surface of the Faraday cage. The systems may include an annular tube holder that supports the dielectric tube atop the dual-channel showerhead assembly. The second gas source may be coupled with a gas inlet disposed on a lateral side of the dual-channel showerhead assembly. The first gas source may include an input manifold. The first plurality of apertures may extend from a top surface of the showerhead to a bottom surface of the showerhead. The second plurality of apertures may extend from a plenum formed within an interior of the dual-channel showerhead assembly and through the bottom surface of the showerhead. The systems may include at least one RF strap extending between the RF power source and the inductively coupled plasma source. The systems may include a housing extending about the inductively coupled plasma source. The housing may define one or more vents. The systems may include one or more fans that are fluidly coupled with the one or more vents. The systems may include a chamber body that at least partially defines a processing region of a semiconductor processing chamber. The systems may include a chamber lid positioned atop the chamber body. The chamber lid may support the dual-channel showerhead assembly.

Some embodiments of the present technology may encompass semiconductor processing systems. The systems may include an inductively coupled plasma source. The inductively coupled plasma source may include a dielectric tube defining an open interior. The inductively coupled plasma source may include a Faraday cage disposed about an exterior surface of the dielectric tube. The inductively coupled plasma source may include one or more RF coils disposed about an exterior surface of the Faraday cage. The systems may include a lid positioned above the dielectric tube. The systems may include an RF power source positioned on the lid. The RF power source may be electrically coupled with the one or more RF coils. The systems may include a first gas source fluidly coupled with the open interior of the dielectric tube. The systems may include a second gas source. The systems may include a dual-channel showerhead assembly defining a first plurality of apertures and a second plurality of apertures. The first plurality of apertures may be fluidly coupled with the open interior of the dielectric tube. The second plurality of apertures may be fluidly coupled with the second gas source.

In some embodiments, the inductively coupled plasma source may include an insert block that is positioned atop the dielectric tube. A portion of the insert block may extend into the open interior of the dielectric tube. The insert block may define a plurality of gas lumens that fluidly couple the first gas source with the open interior of the dielectric tube. The systems may include a cooling fluid source disposed on the lid. The systems may include one or more cooling channels extending between the cooling fluid source and the insert block. The systems may include a chamber body that at least partially defines a processing region of a semiconductor processing chamber. The systems may include a chamber lid positioned atop the chamber body. The chamber lid may support the dual-channel showerhead assembly. The chamber lid may define an aperture that provides access to the processing region of the semiconductor processing chamber. The systems may include a substrate support disposed beneath the dual-channel showerhead within the semiconductor processing chamber. The dielectric tube may include quartz or aluminum oxide.

Some embodiments of the present technology encompass methods of processing a substrate. The methods may include flowing a first gas into an interior of an inductively coupled plasma source. The methods may include supplying an RF current to one or more RF coils of the inductively coupled plasma source to generate a plasma within the interior of the inductively coupled plasma source. The methods may include flowing the plasma into a processing region of a semiconductor processing chamber. The methods may include flowing a second gas into the processing region. The methods may include depositing a material on a substrate positioned within the processing region of the semiconductor processing chamber.

In some embodiments, the plasma may be flowed into the processing region via a first plurality of apertures of a dual-channel showerhead assembly. The second gas may be flowed into the processing region via a second plurality of apertures of a dual-channel showerhead assembly. The dual-channel showerhead assembly may prevent the plasma and the second gas from mixing until the plasma and the second gas have flowed into the processing region. The methods may include actively cooling the inductively coupled plasma source during generation of the plasma.

Such technology may provide numerous benefits over conventional systems and techniques. For example, embodiments of the present technology may increase the generation of high density radicals and ions to produce higher density films having lower hydrogen contents. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic partial cross-sectional view of an exemplary plasma system according to some embodiments of the present technology.

FIG. 4 shows a schematic partial cross-sectional view of an exemplary dual-channel showerhead assembly according to some embodiments of the present technology.

FIG. 5 is a flowchart of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma deposition and etching processes for fabricating semiconductor integrated circuits typically involve the formation of a plasma from plasma-generating gases that are exposed to electric fields of sufficient power inside the processing chamber to cause the gases to ionize. There are challenges to obtain dense film at low process-temperature with low in-film hydrogen contents (which may cause instability issues). For example, many plasma systems utilize remote plasma systems (which may generate plasmas with higher flux than capacitively coupled plasma systems) to generate plasma that is transported to a processing region of a semiconductor processing system. However, due to the large distance the plasma must travel from the remote plasma system to the processing chamber, many radicals within the plasma are lost prior to reaching the processing region, which may reduce the film density on wafer. Additionally, many conventional deposition and/or etch systems operate at high temperatures (e.g., exceeding 400-500° C.), which may lead to damage to chamber components and/or defects on the wafer.

The present technology overcomes these challenges by incorporating an inductively coupled plasma source proximate a processing region of a semiconductor processing chamber. The inductively coupled plasma source may generate a higher plasma flux than capacitively coupled plasma systems, which may help increase film density on wafer. For example, the inductively coupled plasma source may be positioned proximate a showerhead that delivers the plasma to the processing region. The short distance between the inductively coupled plasma source and the processing region may prevent radicals from being lost and may enable a higher density plasma to reach the wafer. Embodiments may also utilize a dual-channel showerhead assembly which may improve diffusion of the plasma within the processing region and may maintain uniformity on wafer regardless of process volume structure by separating the plasma from a reactive gas until reaching the processing region. Additionally, the dual-channel showerhead assembly may act as an ion suppressor to control the mixing of radicals/ions with the reactive precursors on the wafer. As a result, the present technology may operate at low temperatures to generate high density films having low in-film hydrogen contents.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include pedestals according to embodiments of the present technology before additional variations and adjustments to this system according to embodiments of the present technology are described.

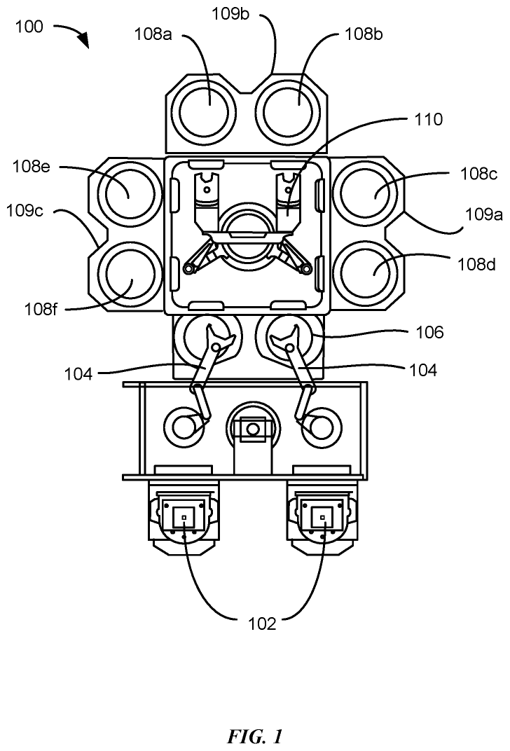

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

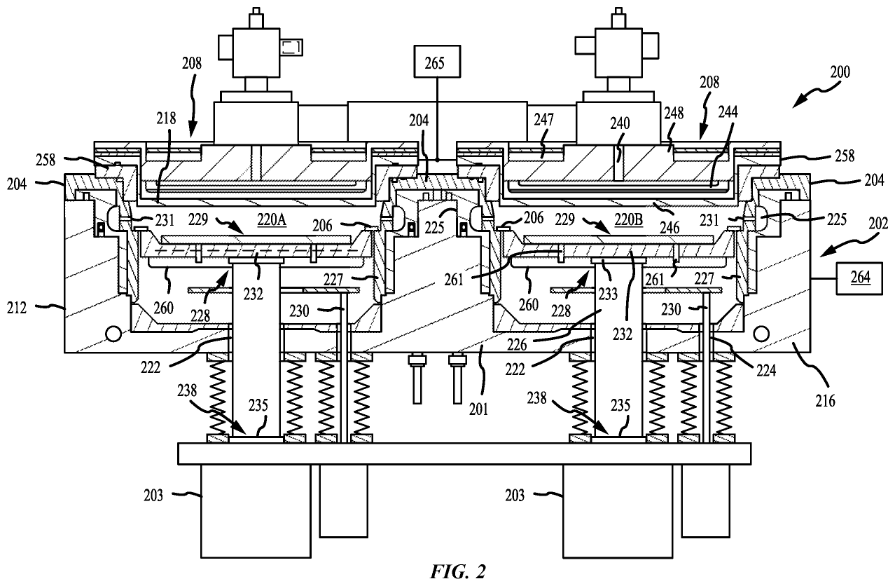

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include substrate support assemblies according to embodiments of the present technology. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the gas distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

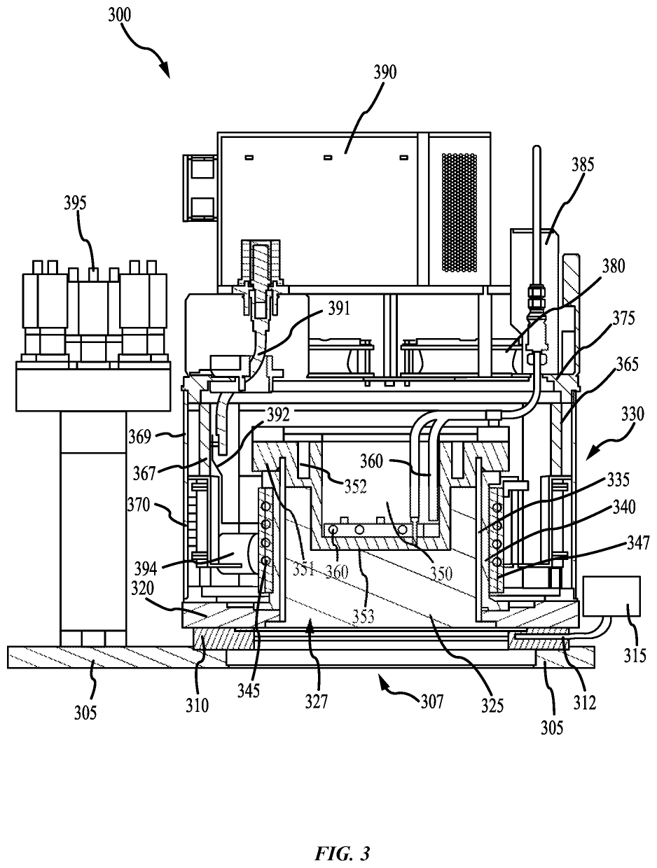

FIG. 3 shows a schematic partial cross-sectional view of an exemplary semiconductor processing system 300 according to some embodiments of the present technology. FIG. 3 may include one or more components discussed above with regard to FIG. 2, and may illustrate further details relating to that system. The system 300 may be used to perform semiconductor processing operations including deposition of stacks of dielectric materials and/or etch operations. System 300 may show a partial view of a gas distribution system of a semiconductor processing system, and may not include all of the components, such as additional lid stack components previously described, which are understood to be incorporated in some embodiments of system 300.

As noted, FIG. 3 may illustrate a portion of a processing system 300. The system 300 may include a chamber lid 305, which may be supported (directly or indirectly) atop a chamber body (similar to chamber body 202 described above), which may at least partially define a processing region of a semiconductor processing chamber. Chamber lid 305 may define one or more apertures 307 therethrough, which may each provide access to a processing region of a respective semiconductor processing chamber. For example, the chamber body may include a pedestal and/or other substrate support that is coaxial with the aperture 307 and which may define a lower boundary of the processing region. The chamber lid 305 may support a dual-channel showerhead assembly 310. Dual-channel showerhead assembly 310 may define at least two fluid paths that are fluidly isolated from one another. For example, the dual-channel showerhead assembly 310 may define a first plurality of apertures that extend from a top surface of the dual-channel showerhead assembly 310 through a bottom surface of the dual-channel showerhead assembly 310. The dual-channel showerhead assembly 310 may define a plenum and/or a number of channels (not shown) within an interior of the dual-channel showerhead assembly 310, with the plenum and/or channels being fluidly isolated from the first plurality of apertures. A second plurality of apertures that extend from the plenum and/or channels through the bottom surface of the dual-channel showerhead assembly 310. The dual-channel showerhead assembly 310 may include one or more gas inlets 312, which may be formed on a lateral side of the dual-channel showerhead assembly 310 and may be fluidly coupled with the plenum and/or channels. Each gas inlet 312 may be used to couple a gas source 315 to the plenum and/or channels and to the second plurality of apertures.

System 300 may include an adapter plate 320 that may be seated atop the dual-channel showerhead assembly 310. The adapter plate 320 may be generally annular in shape and may define an open interior. Adapter plate 320 may be formed from a conductive material, such as aluminum, and may serve as a heat sink during generation of plasma. Adapter plate 320 may also provide support for and/or serve as a mounting location for a tube holder 325. For example, the tube holder 325 may be mounted to a top or a bottom surface of the adapter plate 320. As illustrated, the tube holder 325 includes an annular body portion 327 that is disposed within an interior of the adapter plate 320. The tube holder 325 may include a bottom flange 324 that extends laterally outward from a base of the body portion 327 and is disposed under a bottom surface of the adapter plate 320. The bottom flange 324 may be fastened or otherwise coupled with the bottom surface of the adapter plate 320. The adapter plate 320 and/or tube holder 325 may support an inductively coupled plasma source 330 atop the dual-channel showerhead assembly 310.

The inductively coupled plasma source 330 may include a dielectric tube 335 that defines an open interior. The interior of the dielectric tube 335 may define at least a portion of a plasma volume in which plasma may be generated and allowed to expand prior to passing through the dual-channel showerhead assembly 310. For example, the first plurality of apertures of the dual-channel showerhead assembly 310 may be fluidly coupled with the open interior of the dielectric tube 335 to deliver plasma generated within the inductively coupled plasma source 330 to the processing region of the semiconductor processing chamber. The dielectric tube 330 may be formed of a dielectric material such as, but not limited to, quartz and/or aluminum oxide. The inductively coupled plasma source 330 may include a Faraday cage 340 disposed about an exterior surface of the dielectric tube 335. The Faraday cage 340 may protect the dielectric tube 335 from high thermal load, which may be important to help protect O-rings or other seals that maintain a vacuum seal within the inductively coupled plasma source 330. Additionally, the Faraday cage 340 may reduce external noise and/or other interference in the field distributions, which may help in stabilizing the plasma generated within the inductively coupled plasma source 330. One or more RF coils 345 may be provided about an exterior surface of the Faraday cage 340. In some embodiments, the RF coils 345 may be mounted on a coil support 347 that may extend about the Faraday cage 340. The RF coils 345 may receive an RF current to create an alternating magnetic field within the dielectric tube 335. When a precursor gas is introduced into this alternating magnetic field, the alternating magnetic field may accelerate electrons within the precursor gas to generate a plasma.

The inductively coupled plasma source 330 may include an insert block 350. Insert block 350 may include an outer portion 351 that is seated atop the dielectric tube 335 and/or the Faraday cage 340. An inner portion 353 of the insert block 350 may extend downward into the interior of the dielectric tube 335. The insert block 350 may define a number of gas lumens 352 that may serve as delivery conduits for a precursor gas into the inductively coupled plasma source 330. In some embodiments, the gas lumen 352 may distribute a gas downward along inner walls within an outer region of the dielectric tube 335. Gas lumen 352 may be annular in shape and couple with one or more inlets (not shown) that deliver gas to the outer gas lumens 352a from a gas source. In some embodiments, the gas lumens 352 may also include additional gas lumens (not shown, and which may or may not include a diffuser) that may extend through a base of the inner portion 353 to distribute precursor gas into central region of the dielectric tube 335. A number of cooling channels 360 may be disposed within the insert block 350 to deliver a cooling fluid, such as water, to the insert block 350. For example, the cooling channels 360 may extend through the interior of the insert block 350 and form a recursive path within a base of the insert block 350. The cooling fluid may circulate through the insert block 350 to help cool the interior the dielectric tube 335 during plasma formation.

The inductively coupled plasma source 330 may include a housing 365, which may extend about and enclose the inductively coupled plasma source 330. The housing 365 may include one or more components, which may define an outer periphery of the inductively coupled plasma source 330 and may support additional components of system 300 that are positioned atop the inductively coupled plasma source 330. For example, the housing 365 may include a housing body 367 and one or more panels 369 that provide an outer surface of the housing 365. The panels 369 and/or housing body 367 may define or more vents 370 that may be used to draw air into the inductively coupled plasma source 330 to help cool the inductively coupled plasma source 330 during generation of plasma. For example, the housing body 367 may be laterally spaced apart from the RF coils 345 and/or coil support 347, with the space between the components forming an air channel that extends along an outside of the RF coils 345, Faraday cage 340, and/or dielectric tube 335.

The system 300 may include a lid 375 seated atop the housing 365, which may seal the interior of the inductively coupled plasma source 330. The lid 375 may also support one or more components that are positioned above the inductively coupled plasma source 330. For example, a number of fans 380 may be seated, directly or indirectly, atop the lid 375. Any number of fans 380 may be included. In some embodiments, the system 300 may include at least or about one fan, at least or about two fans, at least or about three fans, at least or about four fans, or more. The fans 380 may be fluidly coupled with the air channel and the vents 370. This may enable the fans 380 to draw air into the housing 365 via the vents 370 upward through the air channel and toward the fans 380 to cool the RF coils 345, Faraday cage 340, and/or dielectric tube 335 during formation of plasma.

A cooling fluid source 385 may be disposed on the lid 375. The cooling fluid source 385 may be coupled with the cooling channels 360. The cooling fluid source 385 may include a pump or other circulation device and may circulate a cooling fluid, such as water, within the cooling channels 360 to cool the insert block 350 and interior of the dielectric tube 335 while plasma is being generated. Oftentimes, the cooling fluid may be maintained at temperatures of between about 50° C. and 75° C.

An RF power source 390, such as an RF match, may be positioned atop the lid 375. The RF power source may be electrically coupled with the RF coils 345 and may supply an RF current to the RF coils 345. For example, an RF rod 391 may extend downward from the RF power source 390 and may be coupled with one or more RF straps 392. The RF straps 392 may extend downward along an interior side of the inductively coupled plasma source 330 and may electrically couple with the RF coils 345. The RF coils may be grounded using a capacitor 394, which may be disposed within the housing 365 proximate the RF coils 345. The RF rod 391 and RF straps 392 may form an RF current path that carries the RF current from the RF power source 390 to the RF coils 345 for generating the alternating magnetic field within the interior of the dielectric tube 335.

System 300 may include an input manifold 395, which may be fluidly coupled with the insert block 350 and the interior of the dielectric tube 335. For example, a lateral side of the housing 365 and/or the insert block 350 may define one or more fluid ports (not shown) that may be coupled with an outlet of the input manifold 395. The input manifold 395 may then supply a precursor gas to the gas lumens 352 for delivery into the interior of the dielectric tube 335 for generation of the plasma. The input manifold 395 may be supported atop the lid 375 in some embodiments. In other embodiments, the input manifold 395 may be seated atop the chamber lid 305 and may be positioned alongside the inductively coupled plasma source 330.

In operation, a precursor gas, such as a plasma generating gas and/or plasma excited species, may be flowed from the input manifold 395 into the interior of the dielectric tube 335 via the fluid ports and/or gas channels 352 of the insert block 350. The RF power source 390 may deliver an RF current to the RF coils 345 via the RF rod 391 and RF strap 392. The RF current flowing through the RF coils 345 may generate an oscillating magnetic field within the interior of the dielectric tube 335, which may accelerate electrons of the precursor gas to generate a plasma within the interior of the dielectric tube 335. The plasma may expand within the volume of the interior of the dielectric tube 335, which may help improve the diffusion of the plasma to peripheral regions of the dual-channel showerhead assembly 310. The plasma may flow downward through the first plurality of apertures of the dual-channel showerhead assembly 310, where the plasma may be introduced into the processing region of the semiconductor processing chamber. A second gas, such as a gas/precursor mixture, may be flowed from gas source 315 into the processing region via the gas inlet 312 and the second plurality of apertures of the dual-channel showerhead assembly 310. The plasma and the second gas may then mix within the processing region proximate a substrate and may react to deposit a material on the exposed surfaces of the substrate, etch materials from the substrate, or both, depending on the process performed. During generation of the plasma, the inductively coupled plasma source 330 may be actively cooled, which may help prevent creep and/or other thermal damage due to the large amount of heat generated during the formation of plasma. For example, cooling fluid from the cooling fluid source 385 may be circulated through the cooling channels 360 to cool the insert block 350 and interior of the dielectric tube 335, ambient air may be drawn through the vents 370 by fans 380 to cool an outer surface of the dielectric tube 335, and/or heat may be dissipated from the dielectric tube 335 by the adapter plate 320 (and/or other components) acting as a heat sink. Other cooling mechanisms may be utilized in various embodiments.

By using an inductively coupled plasma source 330 proximate the dual-channel showerhead 310 and the processing region, high density plasmas (and radicals, such as H, N, O, F, etc.) may be generated with lower in-film hydrogen contents. The high radical density generated using the inductively coupled plasma source 330 near the dual-channel showerhead assembly 310 may enable the deposition and/or etch processes to be performed at lower temperatures (e.g., less than or about 500° C., less than or about 450° C., less than or about 400° C., less than or about 350° C., or less) without the radicals decaying prior to reaching the processing region. The lower operating temperatures may prevent materials on the substrate from melting, decomposing, or otherwise being damaged. Using the dual-channel showerhead assembly 310 in conjunction with the inductively coupled plasma source 330 may enable the on-wafer mixing of radicals/ions from the plasma with the reactive precursors of the second gas to be precisely controlled. For example, the dual-channel showerhead assembly 310 may act as an ion blocker and may trap and/or otherwise regulate ions entering the chamber. The dual-channel showerhead assembly 310 may also help mix the radicals with reactive gases within the processing region.

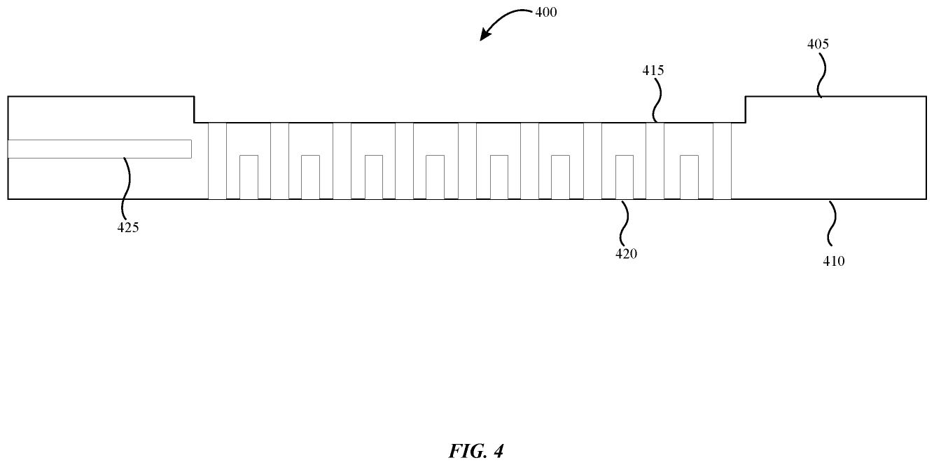

FIG. 4 shows a schematic partial cross-sectional view of an exemplary dual-channel showerhead 400 according to some embodiments of the present technology. FIG. 4 may include one or more components discussed above with regard to FIGS. 2 and 3, and may illustrate further details relating to those systems. The showerhead 400 may be used to perform semiconductor processing operations including deposition of stacks of dielectric materials and/or etch operations. Showerhead 400 may be used as dual-channel showerhead assembly 310 and may include any of the features related to that showerhead assembly.

Showerhead 400 may be characterized by a top surface 405, which may face an inductively coupled plasma source as described above, and a bottom surface 410, which may face a processing region of a semiconductor processing chamber. Showerhead 400 may define a first plurality of apertures 415 and a second plurality of apertures 420. The first plurality of apertures 415 may allow plasma generated by an inductively coupled plasma source to pass through the showerhead 400 into a processing region of a semiconductor processing chamber, while the second plurality of apertures 420 allows a precursor gas, such as a silicon precursor, etchants etc., to pass into the processing region. In some embodiments, the first plurality of apertures 415 may be through holes that extend from the top surface 405 of the showerhead 400 through the bottom surface 410 of the showerhead 400. In one embodiment, there may be between about 60 and about 2000 of the first plurality of apertures 415. The first plurality of apertures 415 may have a variety of shapes but may be generally round and may likewise be cylindrical, conical, or any combination thereof. The second plurality of apertures 420 may extend partially through the showerhead 400 from the bottom surface 410 of the showerhead 400 partially through the showerhead 400. For example, the second plurality of apertures 420 may be coupled with or connected to a plenum and/or a plurality of channels (not shown) that deliver the precursor gas (e.g., deposition compounds, etchants, etc.) to the second plurality of apertures from an external gas source (not shown) via a gas inlet 425. The number of second plurality of apertures 420 may be between about 100 and about 5000 or between about 500 and about 2000 in different embodiments. The second plurality of apertures 420 may be generally round and may likewise be cylindrical, conical, or any combination thereof. Both the first and second plurality of apertures may be evenly distributed over the bottom surface 410 of the showerhead 400 to promote even mixing of the plasma and precursor gases.

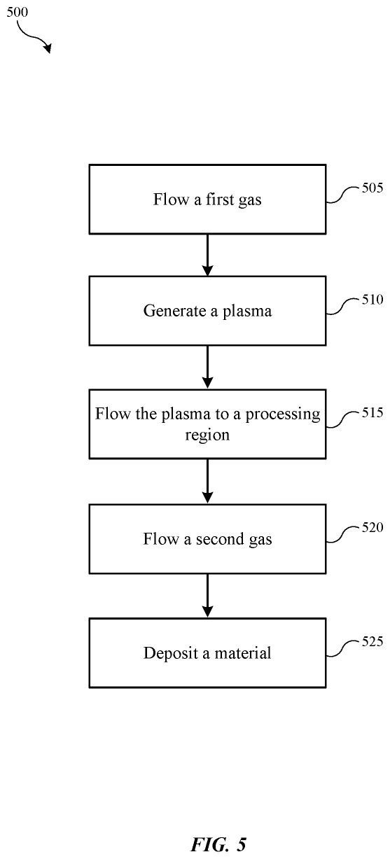

FIG. 5 shows operations of an exemplary method 500 of semiconductor processing according to some embodiments of the present technology. The method 500 may be performed in a variety of processing chambers, including processing systems 200 and 300 described above, which may include inductively coupled plasma systems according to embodiments of the present technology, such as inductively coupled plasma system 330. Method 500 may include a number of optional operations, which may or may not be specifically associated with some embodiments of methods according to the present technology.

Method 500 may include a processing method that may include operations for forming a hardmask film or other deposition and/or etch operations. The method may include optional operations prior to initiation of method 500, or the method may include additional operations. For example, method 500 may include operations performed in different orders than illustrated. In some embodiments, method 500 may include flowing a first gas into an interior of an inductively coupled plasma source at operation 505. For example, the first gas may include a plasma generating gas such as, but not limited to, CF4, NH3, NF3, Ar, He, H2O, H2, O2. An RF current may be supplied to one or more RF coils of the inductively coupled plasma source to generate a plasma within the interior of the inductively coupled plasma source at operation 510. For example, the RF current may cause the RF coils to generate an oscillating magnetic field within a dielectric tube of the inductively coupled plasma source. This oscillating magnetic field may accelerate electrons within the first gas and generate a plasma of the first gas. The method 500 may include actively cooling the inductively coupled plasma source during generation of the plasma. For example, cooling fluid and/or air may be circulated about the inductively coupled plasma source and/or one or more heat sinks may be used to dissipate heat and/or otherwise cool the inductively coupled plasma source during plasma formation. The plasma may be flowed into a processing region of a semiconductor processing chamber at operation 515. For example, the plasma may be flowed into the processing region via a first plurality of apertures of a dual-channel showerhead assembly. The first plurality of apertures may extend from a top surface of the dual-channel showerhead assembly to a bottom surface of the dual-channel showerhead assembly and may fluidly couple the interior of the inductively coupled plasma source with the processing region of the chamber.

Method 500 may include flowing a second gas into the processing region at operation 520. The second gas may include a gas/precursor mixture and may depend on the operation being performed. For example, the second gas may include deposition compounds (e.g., Si-containing compounds) for deposition processes and etchants for etch processes. The second gas may be flowed into the processing region via a second plurality of apertures of a dual-channel showerhead assembly. The first plurality and the second plurality of apertures of the dual-channel showerhead assembly may be fluidly isolated from one another such that the dual-channel showerhead assembly may prevent the plasma and the second gas from mixing until the plasma and the second gas have flowed into the processing region. A material may be deposited on a substrate positioned within the processing region of the semiconductor processing chamber at operation 525. Additionally or alternatively to depositing a material, additional processes may be performed. As just one example, one or more densifying operations may be performed to increase the quality of a dielectric material. In disclosed embodiments, once a determined amount of dielectric material has been formed, the introduction and flow of a silicon-containing precursor may be stopped. However, the plasma effluents may be continued to be produced and directed into the substrate processing region at the formed dielectric layer to densify the formed dielectric material. In some embodiments, the densified dielectric layer may be material that has been deposited at operation 525. In other embodiments, method 500 may omit operation 525 and may be used only to densify a dielectric layer of a substrate fabricated in another chamber and/or process.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing system, comprising:
an inductively coupled plasma source;
an RF power source that is electrically coupled with the inductively coupled plasma source;
a first gas source fluidly coupled with the inductively coupled plasma source;
a second gas source;
a dual-channel showerhead assembly defining a first plurality of apertures and a second plurality of apertures, wherein:
the first plurality of apertures are fluidly coupled with the inductively coupled plasma source; and
the second plurality of apertures are fluidly coupled with the second gas source.

2. The semiconductor processing system of claim 1, wherein:
the inductively coupled plasma source comprises;
a dielectric tube defining an open interior;
a Faraday cage disposed about an exterior surface of the dielectric tube; and
one or more RF coils disposed about an exterior surface of the Faraday cage.

3. The semiconductor processing system of claim 2, further comprising:
an annular tube holder that supports the dielectric tube atop the dual-channel showerhead assembly.

4. The semiconductor processing system of claim 1, wherein:
the second gas source is coupled with a gas inlet disposed on a lateral side of the dual-channel showerhead assembly.

5. The semiconductor processing system of claim 1, wherein:
the first gas source comprises an input manifold.

6. The semiconductor processing system of claim 1, wherein:
the first plurality of apertures extend from a top surface of the showerhead to a bottom surface of the showerhead; and
the second plurality of apertures extend from a plenum formed within an interior of the dual-channel showerhead assembly and through the bottom surface of the showerhead.

7. The semiconductor processing system of claim 1, further comprising:
at least one RF strap extending between the RF power source and the inductively coupled plasma source.

8. The semiconductor processing system of claim 1, further comprising:
a housing extending about the inductively coupled plasma source, the housing defining one or more vents; and
one or more fans that are fluidly coupled with the one or more vents.

9. The semiconductor processing system of claim 1, further comprising:
a chamber body that at least partially defines a processing region of a semiconductor processing chamber; and
a chamber lid positioned atop the chamber body, the chamber lid supporting the dual-channel showerhead assembly.

10. A semiconductor processing system, comprising:
an inductively coupled plasma source, comprising:
a dielectric tube defining an open interior;
a Faraday cage disposed about an exterior surface of the dielectric tube; and
one or more RF coils disposed about an exterior surface of the Faraday cage;
a lid positioned above the dielectric tube;
an RF power source positioned on the lid, the RF power source being electrically coupled with the one or more RF coils;
a first gas source fluidly coupled with the open interior of the dielectric tube;
a second gas source;
a dual-channel showerhead assembly defining a first plurality of apertures and a second plurality of apertures, wherein:
the first plurality of apertures are fluidly coupled with the open interior of the dielectric tube; and
the second plurality of apertures are fluidly coupled with the second gas source.

11. The semiconductor processing system of claim 10, wherein:
the inductively coupled plasma source comprises an insert block that is positioned atop the dielectric tube;
a portion of the insert block extends into the open interior of the dielectric tube; and
the insert block defines a plurality of gas lumens that fluidly couple the first gas source with the open interior of the dielectric tube.

12. The semiconductor processing system of claim 11, further comprising:
a cooling fluid source disposed on the lid; and
one or more cooling channels extending between the cooling fluid source and the insert block.

13. The semiconductor processing system of claim 10, further comprising:
a chamber body that at least partially defines a processing region of a semiconductor processing chamber; and
a chamber lid positioned atop the chamber body, the chamber lid supporting the dual-channel showerhead assembly.

14. The semiconductor processing system of claim 13, wherein:
the chamber lid defines an aperture that provides access to the processing region of the semiconductor processing chamber.

15. The semiconductor processing system of claim 13, further comprising:
a substrate support disposed beneath the dual-channel showerhead within the semiconductor processing chamber.

16. The semiconductor processing system of claim 10, wherein:
the dielectric tube comprises quartz or aluminum oxide.

17. A method of processing a substrate, comprising:
flowing a first gas into an interior of an inductively coupled plasma source;
supplying an RF current to one or more RF coils of the inductively coupled plasma source to generate a plasma within the interior of the inductively coupled plasma source;
flowing the plasma into a processing region of a semiconductor processing chamber;
flowing a second gas into the processing region; and
depositing a material on a substrate positioned within the processing region of the semiconductor processing chamber.

18. The method of processing a substrate of claim 17, wherein:
the plasma is flowed into the processing region via a first plurality of apertures of a dual-channel showerhead assembly; and
the second gas is flowed into the processing region via a second plurality of apertures of a dual-channel showerhead assembly.

19. The method of processing a substrate of claim 18, wherein:
the dual-channel showerhead assembly prevents the plasma and the second gas from mixing until the plasma and the second gas have flowed into the processing region.

20. The method of processing a substrate of claim 17, further comprising:
actively cooling the inductively coupled plasma source during generation of the plasma.
